(19) United States
(12) Patent Application Publication
(10) Pub. No.: US 2007/0105365 A1
(43) Pub. Date: May 10, 2007

(54) Metal printing blanket

(75) Inventors: Eduard Hoffmann, Bobingen (DE); Thomas Kandlbinder, Augsburg (DE)

Correspondence Address: COHEN, PONTANI, LIEBERMAN & PAVANE, 551 FIFTH AVENUE, SUITE 1210, NEW YORK, NY, 10176, US

(73) Assignee: MAN Roland Druckmaschinen AG

(21) Appl. No.: 11/583,208

(22) Filed: Oct. 19, 2006

(30) Foreign Application Priority Data
Oct. 20, 2005 (DE) 10 2005 050 226.1

(51) Int. Cl. H01L 21/4763

(52) U.S. Cl. 438/620

(57) ABSTRACT

The metal printing blanket includes a supporting layer formed of a metallic material having a relatively high thermal conductivity, and a rubber layer applied to the metallic supporting layer and serving to transfer a print. As an alternative, the metal printing blanket includes a supporting layer formed of a metallic material, a rubber layer serving to transfer a print, and an intermediate layer arranged between the supporting layer and the rubber layer and formed of a metallic material having a relatively high thermal conductivity.

### BACKGROUND OF THE INVENTION

The invention relates to a metal printing blanket.

Metal printing blankets are rubber blankets having a metallic supporting layer, wherein a rubber layer serving to transfer the print is applied to the supporting layer In this case, the rubber layer is preferably vulcanized onto the metallic supporting layer. Using metal printing blankets of this type, which are also designated metal back blankets, the clamping channel on the rubber-covered cylinder can be reduced, so that the rolling behaviour and oscillatory behaviour can be optimized.

In the metal printing blankets known from practice, the supporting layer is formed of a steel having a relatively high nickel content. Supporting layers of metal printing blankets formed in this way have a relatively low thermal conductivity, so that, in the event of local increases in temperature, which are known as hot spots, temperature equalization can be established only very slowly. Such local increases in temperature can lead to deformations of the cylinder and have a detrimental effect overall on the printing process.

### SUMMARY OF THE INVENTION

It is an object of the present invention to provide a novel type of metal printing blanket.

According to a first preferred embodiment of the present invention, the metallic supporting layer is formed of a metallic material having a relatively high thermal conductivity.

According to a second preferred embodiment of the present invention, an intermediate layer of a metallic material having a relatively high thermal conductivity is arranged between the metallic supporting layer and the rubber layer.

According to the present invention, either the supporting layer or an intermediate layer positioned between the supporting layer and the rubber layer is formed of a metallic material having a relatively high thermal conductivity. As a result, in the case of an undesired local increase in temperature, temperature equalization can be established relatively quickly, so that the risk of undesired cylinder deformations which impair the printing process is minimized

Preferred developments of the invention emerge from the dependent claims and the following description.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

An exemplary embodiment of the invention, without being restricted thereto, will be explained in more detail with reference to the drawings.

FIG. 1 is a cross-sectional view of a metal printing blanket according to the prior art;

FIG. 2 is a cross-sectional view of a metal printing blanket according to a first embodiment of the present invention; and

FIG. 3 is a cross-sectional view of a metal printing blanket according to a second embodiment of the present invention.

### DETAILED DESCRIPTION OF THE PRESENTLY PREFERRED EMBODIMENTS

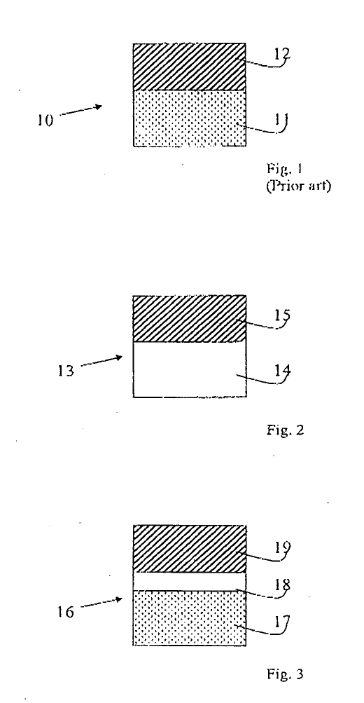

Before the present invention is described in greater detail below with reference to FIGS. 2 and 3, the construction of a metal printing blanket known from the prior art will be described first with reference to FIG. 1.

FIG. 1 shows a metal printing blanket 10 known from the prior art, which comprises a metallic supporting layer 11 and a rubber layer 12 applied to the metallic supporting layer 11 and serving to transfer the print. The rubber layer 12 is preferably vulcanized onto the metallic supporting layer 11. In the metal printing blankets 10 known from the prior art, the metallic supporting layer 11 is formed of a steel having a relatively high nickel content. As a result, the supporting layer 11 has a relatively low thermal conductivity, so that local increases in temperature can be dissipated only very slowly. As a result, there is the risk of forming what are known as hot spots, which can lead to cylinder deformations.

FIG. 2 shows, in schematic form, a metal printing blanket 13 according to a first embodiment of the invention, which comprises a metallic supporting layer 14 and a rubber layer 15 applied to the metallic supporting layer 14. In the exemplary embodiment of FIG. 2, the supporting layer 14 is formed of a metallic material having a relatively high thermal conductivity, the thermal conductivity of the metallic material of the supporting layer 14 being relatively high as compared with the thermal conductivity of stainless steel.

The thermal conductivity of the metallic material of the supporting layer 14 is preferably at least 90 W/m K, or even greater than 200 W/m K. The material of the metallic supporting layer 14 is copper or zinc or a copper-zinc alloy such as brass, or aluminum or an aluminum alloy. If appropriate, the material of the supporting layer 14 can be a steel having a relatively low carbon component of less than 0.2%.

FIG. 3 shows a metal printing blanket 16 according to a second embodiment of the invention, the metal printing blanket 16 of FIG. 3 comprising a metallic supporting layer 17, a rubber layer 19 and an intermediate layer 18 positioned between the supporting layer 17 and the rubber layer 19.

The supporting layer 17 can in this case be formed of a metallic material having a relatively low thermal conductivity. On the other hand, the metallic intermediate layer 18 is formed of a metallic material having a relatively high thermal conductivity, specifically of a material which has a relatively high thermal conductivity as compared with the material of the supporting layer 17. Here, the thermal conductivity of the metallic material of the intermediate layer 18 is preferably greater than 90 W/m K, or even greater than 200 W/m K. The metallic material of the intermediate layer 18 can again be copper or zinc or a copper-zinc alloy such as brass, or aluminum or an aluminum alloy. The intermediate layer 18 can be applied to the supporting layer 17 as a thin sheet.

Overall, the metallic printing blankets 13 and 16 according to the invention have a relatively high thermal conductivity, so that local increases in temperature, which can be formed during the printing operation, can be equalized in a relatively short time. In this way, the risk of cylinder deformations is minimized.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements which perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A metal printing blanket comprising:
a supporting layer formed of a metallic material having a high thermal conductivity; and
a rubber layer applied to the metallic supporting layer and serving to transfer a print.

2. The metal printing blanket of claim 1, wherein the thermal conductivity of the metallic material of the supporting layer is relatively high compared with a thermal conductivity of stainless steel.

3. The metal printing blanket of claim 1, wherein the thermal conductivity of the metallic material of the supporting layer is greater than 90 W/m K.

4. The metal printing blanket of claim 3, wherein the metallic material is copper or zinc or brass.

5. The metal printing blanket of claim 1, wherein the thermal conductivity of the metallic material of the supporting layer is greater than 200 W/m K.

6. The metal printing blanket of claim 5, wherein the metallic material is aluminum or an aluminum alloy.

7. A metal printing blanket comprising:
a supporting layer formed of a metallic material;
a rubber layer serving to transfer a print; and
an intermediate layer arranged between the supporting layer and the rubber layer and formed of a metallic material having a high thermal conductivity.

8. The metal printing blanket of claim 7, wherein the thermal conductivity of the metallic material of the intermediate layer is relatively high compared with a thermal conductivity of the metallic material of the supporting layer.

9. The metal printing blanket of claim 7, wherein the thermal conductivity of the metallic material of the intermediate layer is greater than 90 W/m K.

10. The metal printing blanket of claim 9, wherein the metallic material of the intermediate layer is copper or zinc or brass.

11. The metal printing blanket of claim 7, wherein the thermal conductivity of the metallic material of the intermediate layer is greater than 200 W/m K.

12. The metal printing blanket of claim 11, wherein the metallic material is aluminum or an aluminum alloy.
